(19) United States
(12) Patent Application Publication
(10) Pub. No.: US 2025/0273973 A1
(43) Pub. Date: Aug. 28, 2025

(54) LOW BATTERY PROTECTION METHOD, DEVICE, AND MEDIA

(71) Applicant: GUANGZHOU ISSYZONE TECHNOLOGY CO., LIMITED, Guangzhou (CN)

(72) Inventors: TAIPING YANG, Shenzhen (CN); ZEGANG YE, Shenzhen (CN)

(21) Appl. No.: 18/628,970

(22) Filed: Apr. 8, 2024

(30) Foreign Application Priority Data
Feb. 23, 2024 (CN) 202410202675.8

(51) Int. Cl. H02J 7/00; G01R 31/367; G01R 31/379; G01R 31/387; G01R 31/396

(52) U.S. Cl. CPC H02J 7/0031; G01R 31/367; G01R 31/379; G01R 31/387; G01R 31/396

(57) ABSTRACT

A low battery protection method, device, and medium are provided, the method includes: obtaining a historical maximum starting current of an engine, detecting a real-time battery level of the battery, obtaining a pre-stored battery characteristic table, the battery characteristic table includes a mapping relationship between a battery capacity and a maximum instantaneous discharge current of the battery; selecting a maximum instantaneous discharge current that is higher than the historical maximum starting current, forming a set of battery levels corresponding to the maximum instantaneous discharge currents, taking the battery level with a smallest value from the set as a target battery level; when the real-time battery level is lower than the target battery level, cutting off a power coupling between the battery and an external device of a vehicle, which can effectively reduce a self-consumption of the battery.

### CROSS-REFERENCE TO RELATED APPLICATIONS

This application claims priority to Chinese Patent Application No. 202410202675.8, filed on Feb. 23, 2024, which is hereby incorporated by reference in its entirety.

TECHNICAL FIELD

The present disclosure relates to the field of vehicle starting power supply technologies, and in particular, to a low battery protection method, device, and medium.

BACKGROUND

Lead acid batteries are widely used in automotive batteries, motorcycles, lawn mowers, motorboats, and skis, for device ignition and external electronic device power supply.

When the vehicle is left idle for a long time, the lead-acid battery will lose power,

causing it to be unable to start. At this time, an emergency starting power supply can only be called to connect, causing great inconvenience to the users. The reason is that an external electronic device (such as an anti-theft system and a remote-control system) of the vehicle will still self-consume electricity after the vehicle is turned off. When the vehicle is not started, the engine cannot charge the battery, a peripheral device will gradually drain the battery, Moreover, there is a phenomenon of self-discharge in the battery itself. When the battery voltage is lower than an ignition voltage (a battery level is related to the ignition voltage), the engine will fail to start.

The existing technology cannot bypass a problem of lead-acid batteries needing to continuously supply power to the external device after the vehicle is turned off. Therefore, the solution is more focused on miniaturizing an emergency starting power supply, rendering it easier for the user to accept the emergency starting power supply as a backup device placed on the vehicle. The above emergency power supply connection modes are remedial measures after the battery level drops below the ignition voltage. Moreover, not every user will be provided with an emergency starting power supply in the vehicle. If the emergency power supply cannot be found in a timely manner to connect the battery in extremely harsh environments, the user's life safety cannot be guaranteed.

### SUMMARY

In response to the above issues, the present disclosure proposes a low battery protection method, device, and medium aimed at reducing a self-consumption of a battery.

To solve the above technical problems, a first aspect of the present disclosure proposes a low battery protection method, including the following steps:
obtaining a historical maximum starting current of an engine, detecting a real-time battery level of the battery;
obtaining a pre-stored battery characteristic table that at least includes a mapping relationship between a battery capacity and a maximum instantaneous discharge current of the battery;
globally selecting each maximum instantaneous discharge current that is higher than the historical maximum starting current from the battery characteristic table, forming a set of battery levels corresponding to each selected maximum instantaneous discharge current, taking the battery level with a smallest value from the set as a target battery level.

In some embodiments, when the real-time battery level is lower than the target battery level, a power coupling between the battery and an external device of a vehicle is cut off.

In some embodiments, the battery level with a smallest value is taken from the set as the target battery level, the target battery level is updated in a predetermined manner.

The predetermined manner includes increasing a preset battery level value to the target battery level to form an updated target battery level, comparing the updated target battery level with the real-time battery level based on the updated target battery level.

In some embodiments, the battery characteristic table includes a mapping relationship between battery capacity, battery voltage, discharge rate, and maximum instantaneous discharge current.

In some embodiments, the battery level in the battery characteristic table is an integer multiple of 10.

In some embodiments, a calculation method of the maximum instantaneous discharge current is: obtaining a maximum allowable discharge current of the battery, calculating a maximum instantaneous discharge current based on a product of the maximum discharge current and a corresponding discharge rate.

In some embodiments, the battery characteristic table is tested, calculated, and edited based on a physical parameter of the battery, and written into a register attached to the battery.

In some embodiments, the battery characteristic table cannot be modified.

A second aspect of the present disclosure proposes a low battery protection device, including:
an engine starting current acquisition unit, configured to obtain a historical maximum starting current of an engine,
a battery level acquisition unit, configured to detect a real-time battery level of the battery;
a battery characteristic table acquisition unit, configured to obtain a pre-stored battery characteristic table, which at least includes a mapping relationship between a battery capacity and a maximum instantaneous discharge current of the battery;
a target battery level calculation unit, configured to globally select each maximum instantaneous discharge current that is higher than the historical maximum starting current from the battery characteristic table, form a set of battery levels corresponding to each selected maximum instantaneous discharge current, take battery level with a smallest value from the set as a target battery level;
a power cut-off unit, configured to cut off a power coupling between the battery and an external device of a vehicle when the real-time battery level is lower than the target battery level.

A third aspect of the present disclosure proposes a computer storable medium, a computer instruction is stored thereon, when the computer instruction is called, which is configured to execute the battery low voltage protection method described above.

The beneficial effect of the present disclosure is to calculate a target battery level in real time through a historical maximum starting current of an engine and a pre-stored battery characteristic table. When the real-time battery level of the battery is lower than a target battery level, a power supply coupling between the battery and an external device of a vehicle is immediately cut off, which can effectively reduce a self-consumption of the battery.

### BRIEF DESCRIPTION OF DRAWINGS

FIG. 1 is a flowchart of a low battery protection method disclosed in Embodiment 1 of the present disclosure.

FIG. 2 is a structural schematic diagram of a low battery protection device disclosed in Embodiment 3 of the present disclosure.

### DESCRIPTION OF EMBODIMENTS

In order to render the purpose, technical solution, and advantages of the present disclosure clearer and specific, the following will provide further detailed explanations of the content of the present disclosure in combination with the drawings and specific implementation modes. It can be understood that the specific embodiments described here are only intended to explain the present disclosure and not to limit it. Furthermore, it should be noted that for ease of description, only the relevant parts of the present disclosure are shown in the drawings, rather than the entire content.

### Embodiment 1

This embodiment proposes a low battery protection method, which calculates a target battery level in real time through a historical maximum starting current of an engine and a pre-stored battery characteristic table. When the real-time battery level of the battery is lower than the target battery level, a power supply coupling between the battery and an external device of a vehicle is immediately cut off, which can effectively reduce a self-consumption of the battery.

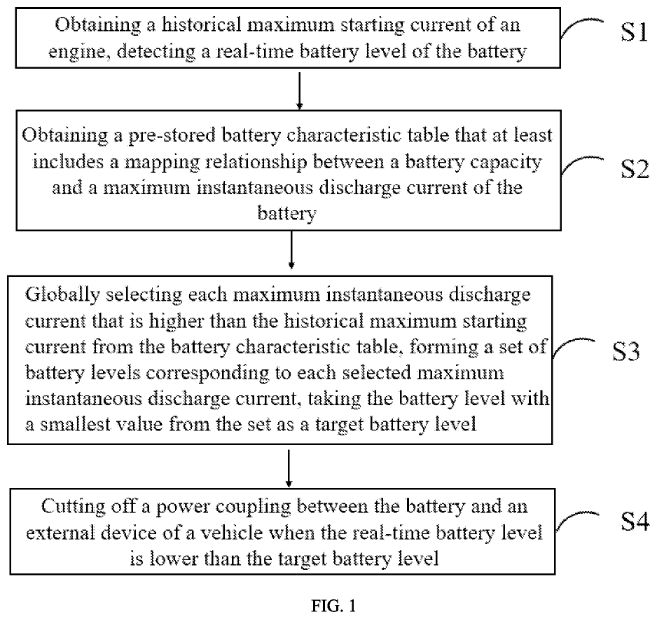

As shown in FIG. 1, this method includes the following steps S1-S4:
S1, obtaining a historical maximum starting current of an engine, detecting a real-time battery level of the battery.

In S1, two important parameters need to be obtained, one of which is the historical maximum starting current Imax of the engine. As low battery protection usually occurs during an idle period of the vehicle, the real-time maximum starting current cannot be obtained, so only the historical maximum starting current can be obtained. Generally speaking, this historical maximum starting current Imax can be stored in a vehicle's controller, which can be the maximum starting current of a most recent ignition. It can also be the maximum starting current in multiple ignition cycles. For example, a program will compare the maximum starting current for each ignition cycle of the vehicle, compare two maximum starting currents, take a larger one as the historical maximum starting current Imax. Obviously, the maximum starting current of a vehicle during ignition will fluctuate to a certain extent. Taking the maximum starting current from multiple ignition tasks as the historical maximum starting current Imax can preliminarily improve a redundancy of the battery. In addition, it is necessary to obtain the real-time battery level of the battery. In this scheme, the battery level refers to a state of charge of the battery. The state of charge is a ratio of a remaining capacity of the battery after being used for a period of time or left unused for a long time to its fully charged capacity, commonly expressed as a percentage, such as 100%, 90%, etc.
S2, obtaining a pre-stored battery characteristic table that at least includes a mapping relationship between a battery capacity and a maximum instantaneous discharge current of the battery.

The battery characteristic table is formed by testing, calculating, and editing a physical parameter of the battery, and is written into a register attached to the battery.

Specifically, the battery characteristic table includes a mapping relationship between battery capacity, battery voltage, discharge rate, and maximum instantaneous discharge current. A lead-acid battery with a capacity of 8 Ah (8V˜14V). A continuous discharge rate is 45 C, an instantaneous discharge rate is 120 C. At the same time, when the vehicle starts, it is an instantaneous discharge, a maximum instantaneous discharge current of the battery should be calculated. A calculation method of the maximum instantaneous discharge current is to obtain a maximum allowable discharge current of the battery, calculate a maximum instantaneous discharge current based on a product of the maximum discharge current and a corresponding discharge rate. Therefore, under a condition of 100% battery capacity, the maximum allowable instantaneous discharge current is 8 Ah×120 C=960 A. When the battery level decreases, the voltage decreases and the discharge rate also decreases, therefore, forming the relationship shown in Table 1.

TABLE 1
Battery Characteristics Table

| Battery level | | | Discharge | Maximum instantaneous |
|---|---|---|---|---|
| Percentage | Voltage | | rate (C) | discharge current (A) |
| 100% | 14 | V | 120 | 960 |
| 90% | 13.5 | V | 100 | 800 |
| 80% | 13.2 | V | 100 | 800 |
| 70% | 13.0 | V | 90 | 720 |
| 60% | 12.5 | V | 90 | 720 |
| 50% | 12.3 | V | 80 | 640 |
| 40% | 12.0 | V | 60 | 480 |
| 30% | 11 | V | 40 | 320 |
| 20% | 10 | V | 20 | 160 |
| 10% | 9 | V | 10 | 80 |
| 0% | 8 | V | 1 | 8 |

Due to different characteristics of each battery, such as a 4 Ah (8V-14V) lead-acid battery, it is necessary to form a voltage, charge, and discharge rate relationship table after separate testing, and then this table is written into the register. Further, S3 is queried below to determine an amount of the battery level that should be reserved. Taking the battery characteristic table shown in Table 1 as an example, in order to reduce the amount of testing, the battery capacity in the battery characteristic table is all multiples of 10.

In addition, the battery characteristic table corresponding to different types and parameters of batteries is different. Therefore, in an implementation mode, the battery characteristic table cannot be modified. After the manufacturer writes it into the register attached to the battery, only the user is allowed to query the data in the battery characteristic table.
S3, globally selecting a maximum instantaneous discharge current that is higher than the historical maximum starting current from the battery characteristic table, forming a set of battery levels corresponding to selected maximum instantaneous discharge currents, taking the battery level with a smallest value from the set as a target battery level.

In this scheme, the target battery level needs to be calculated in real-time as it is unknown which engine the battery will be mounted on. If the historical maximum starting current of the vehicle obtained in S1 is Iₘₐₓ32 300 A, according to the relationship shown in Table 1 in S2, when the battery's charge is between 30-100%, the maximum instantaneous discharge current that the battery can excite is between 320-960A. Among the total 8 charge values of 30-100%, the minimum 30% of the battery's charge is taken as the target charge. In other words, reserving 30% of the battery's charge can meet the engine's starting operation. Obviously, when the real-time battery level of the battery is 30%, the maximum instantaneous discharge current of 320 A at this time satisfies the historical maximum starting current of 300 A. Assuming that under an ideal condition, the self-discharge rate of lead-acid batteries is usually between 0.1% and 0.3% per month, it can be basically considered that the battery has no loss for at least one month without disconnecting an external device connection. Therefore, the battery level with the smallest value can be taken from the set as the target battery level, without considering an issue of decreased battery level.

If the historical maximum starting current Imax of the vehicle is 500 A, 50% of the battery level needs to be reserved. When the battery level drops below 50%, it is necessary to enter a low battery protection and turn off the external device.

In an implementation mode, S301: taking the battery level with a smallest value from the set as a target battery level, updating the target battery level according to the predetermination method. A purpose of this implementation mode is to extend the time for the battery level to decrease below the historical maximum starting current. Taking the above 30% battery level as an example, when the battery level drops to 20%, there is only a maximum instantaneous discharge current of 160 A, which is much lower than a required historical maximum starting current of 300 A. Moreover, the 20-30% battery level in Table 1 is in an untested state. Under the ideal condition, the self-discharge rate of lead-acid batteries is usually between 0.1% and 0.3% per month, but this value is not very accurate. It is impossible to determine how long the battery can maintain above 300 A under self-discharge, so slightly increasing the value of an original target battery level to form an updated target battery level, and using this updated target battery level as a key parameter in S4 can further improve the redundancy of the battery.

Specifically, the predetermination method includes increasing the preset battery level to the target battery level to form an updated target battery level, comparing the updated target battery level with the real-time battery level based on the updated target battery level. Assuming that, 30% of the target battery level is calculated according to S1-S3 above, an additional 2% battery level value can be added to 30%, updated to 32%, as the basis for judging S4. A specific increase in the target battery level mainly depends on the self-discharge rate of the battery. For example, the product requirement of the battery is to ensure that the engine can still start for at least 2 months after disconnecting the peripheral device. Assuming that the battery's self-consumption is 1% per month, then the battery level will still be higher than 30% after 2 months. That is to say, the preset battery level is set to 2%, so that the target battery level can be updated to 32%.
S4, cutting off a power coupling between the battery and an external device of a vehicle when the real-time battery level is lower than the target battery level.

In S4, taking the above 30% battery level as an example, when the battery level drops to 30% (or a 35% update target battery level is used), the system cuts off the power supply coupling between the battery and the external device of the vehicle. Under the ideal condition, the self-discharge rate of lead-acid batteries is usually between 0.1% and 0.3% per month, and the maximum instantaneous discharge current of the battery can still be maintained above 300 A within one month.

On the contrary, if the real-time battery level is lower than the target battery level, the power coupling is restored between the battery and the external device of the vehicle.

### Embodiment 2

On the basis of S1-S4 of Embodiment 1, this embodiment further includes S401:
when the real-time battery level is lower than the target battery level, it is necessary to check whether the battery is in a charging state. If so, execute a power cut-off operation in S4. If not, return to SI to only obtain the real-time battery level of the battery. Skip S2 and S3 and directly perform S4 and S401 operations to re-determine whether the real-time battery level is lower than the target battery level and whether the battery is in a charging state. If the real-time battery level is lower than the target battery level, and the battery is not in a charging state, the power coupling between the battery and the external device of the vehicle is cut off.

A function of S401 is to prevent the battery from being disconnected from the external device while in a charging state, which may cause the external device to malfunction. Assuming that the current battery level is already below 30%, according to the logic of Embodiment 1, it is necessary to immediately cut off the power supply to the external device. Only when the battery level reaches 30% or more, the power supply to the external device can be restored. Therefore, S401 needs to be set to limit the cutting operation, that is, in a case of charging the battery, the power coupling between the battery and the external device of the vehicle will not be cut off. And when the system detects that the battery is not in a charging state, it only needs to retrieve the real-time battery level of the battery, skip S2 and S3, and proceed with S4 and S401 operations.

### Embodiment 3

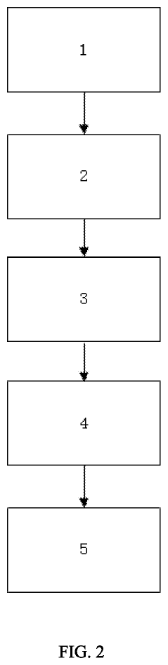

This embodiment proposes a low battery protection device, as shown in FIG. 2, including:
an engine starting current acquisition unit 1, configured to obtain a historical maximum starting current of tan engine,
a battery level acquisition unit 2, configured to detect a real-time battery level of the battery;
a battery characteristic table acquisition unit 3, configured to obtain a pre-stored battery characteristic table, which at least includes a mapping relationship between a battery capacity and a maximum instantaneous discharge current of the battery;
a target battery level calculation unit 4, configured to globally select each maximum instantaneous discharge current that is higher than the historical maximum starting current from the battery characteristic table, form a set of battery levels corresponding to each selected maximum instantaneous discharge current, take the battery level with a smallest value from the set as a target battery level;
a power cut-off unit 5, configured to cut off a power coupling between the battery and an external device of a vehicle when the real-time battery level is lower than the target battery level.

A function of the engine starting current acquisition unit and the battery level acquisition unit in this embodiment correspond to S1 in Embodiment 1 or 2,respectively, while the battery characteristic table acquisition unit, target battery level calculation unit, and power cut-off unit correspond to S2-S4 in Embodiment 1 or 2, respectively.

### Embodiment 4

This embodiment proposes a computer storable medium, a computer instruction is stored thereon. When the computer instruction is called, which is configured to execute the low battery protection method of Embodiment 1 or 2.

The device embodiments described above are only illustrative, where the module described as a separate component can be or may not be physically separated, and the component displayed as a module can be or may not be a physical module, which can be located in one place or distributed across multiple network modules. Some or all modules can be selected according to an actual need to achieve a purpose of this embodiment. Ordinary technical personnel in this field can understand and implement it without creative work.

Through a specific description of the above embodiments, technical personnel in this field can clearly understand that each implementation mode can be achieved through software and necessary general hardware, and of course, it can also be achieved through hardware. Based on this understanding, the above-mentioned technical solutions or the parts that contribute to the existing technology can be reflected in the form of software products, which can be stored in computer-readable storage media, including Read Only Memory (ROM), Random Access Memory (RAM), Programmable Read Only Memory (PROM) Erasable Programmable Read Only Memory (EPROM), One time Programmable Read Only Memory (OTPROM), Electrically Erasable Programmable Read Only Memory (EEPROM), Compact Disc Read Only Memory (CD-ROM) or other optical disc storage, disk storage, magnetic tape storage or any other computer-readable medium that can be used to carry or store data.

Finally, it should be noted that the low battery protection method, device, and medium disclosed in the embodiments of the present disclosure are only the preferred embodiments of the present disclosure, and are only used to illustrate the technical solution of the present disclosure, rather than limiting it; although the present disclosure has been described in detail with reference to the aforementioned embodiments, those skilled in the art should understand; it can still modify the technical solutions recorded in the aforementioned embodiments, or equivalently replace some of the technical features; and these modifications or replacements do not separate the essence of the corresponding technical solutions from the spirit and scope of the various embodiments of the technical solutions.

What is claimed is:

1. A low battery protection method, comprising:
obtaining a historical maximum starting current of an engine, detecting a real-time battery level of the battery;
obtaining a pre-stored battery characteristic table that at least comprises a mapping relationship between a battery capacity and a maximum instantaneous discharge current of the battery;
globally selecting each maximum instantaneous discharge current that is higher than the historical maximum starting current from the battery characteristic table, forming a set of battery levels corresponding to each selected maximum instantaneous discharge current, taking the battery level with a smallest value from the set as a target battery level;
cutting off a power coupling between the battery and an external device of a vehicle when the real-time battery level is lower than the target battery level.

2. The low battery protection method as claimed in claim 1, wherein the battery level with a smallest value is taken from the set as the target battery level, the target battery level is updated in a predetermined manner.

3. The low battery protection method as claimed in claim 2, wherein the predetermined manner comprises: increasing a preset battery level value to the target battery level to form an updated target battery level, comparing the updated target battery level with the real-time battery level based on the updated target battery level.

4. The low battery protection method as claimed in claim 1, wherein the battery characteristic table comprises a mapping relationship between battery capacity, battery voltage, discharge rate, and maximum instantaneous discharge current.

5. The low battery protection method as claimed in claim 4, wherein the battery level in the battery characteristic table is an integer multiple of 10.

6. The low battery protection method as claimed in claim 4, wherein a calculation method of the maximum instantaneous discharge current is: obtaining a maximum allowable discharge current of the battery, calculating a maximum instantaneous discharge current based on a product of the maximum discharge current and a corresponding discharge rate.

7. The low battery protection method as claimed in claim 1, wherein the battery characteristic table is tested, calculated, and edited based on a physical parameter of the battery, and written into a register of the battery.

8. The low battery protection method as claimed in claim 1, wherein the battery characteristic table cannot be modified.

9. A low battery protection device, comprising:
an engine starting current acquisition unit, configured to obtain a historical maximum starting current of an engine,
a battery level acquisition unit, configured to detect a real-time battery level of the battery;
a battery characteristic table acquisition unit, configure to obtain a pre-stored battery characteristic table, which at least comprises a mapping relationship between a battery capacity and a maximum instantaneous discharge current of the battery;
a target battery level calculation unit, configured to globally select each maximum instantaneous discharge current that is higher than the historical maximum starting current from the battery characteristic table, form a set of battery levels corresponding to each selected maximum instantaneous discharge current, take the battery level with a smallest value from the set as a target battery level;
a power cut-off unit, configured to cut off a power coupling between the battery and an external device of a vehicle when the real-time battery level is lower than the target battery level.

10. A computer storable medium, wherein a computer instruction is stored thereon, when called, which is configured to execute the low battery protection method as claimed in claim 1.
